(19) United States
(12) Patent Application Publication
(10) Pub. No.: US 2010/0059754 A1
(43) Pub. Date: Mar. 11, 2010

(54) ORGANIC LIGHT EMITTING DEVICE AND A MANUFACTURING METHOD THEREOF

(76) Inventors: Sang-Pil LEE, Anyang-si (KR); Chang-Mo PARK, Hwaseong-si (KR); Sung-Su HONG, Seoul (KR)

Correspondence Address: F. CHAU & ASSOCIATES, LLC, 130 WOODBURY ROAD, WOODBURY, NY, 11797, US

(21) Appl. No.: 12/466,009

(22) Filed: May 14, 2009

(30) Foreign Application Priority Data
Sep. 11, 2008 (KR) 10-2008-0089822

(51) Int. Cl. H01L 33/00; H01L 21/30

(52) U.S. Cl. 257/59; 438/29; 257/40; 257/E33.053; 257/E21.211

(57) ABSTRACT

An organic light emitting device, wherein a color filter is formed in a display device displaying a color by using a micro-cavity effect, and grooves with a concave lens shape are formed In the surface of the color filter. As a result, the amount of emitted light is increased and the viewing angle is improved due to the grooves with the concave lens shape.

### CROSS-REFERENCE TO RELATED APPLICATION

This application claims priority to and the benefit of Korean Patent Application No. 10-2008-0089822 filed in the Korean Intellectual Property Office on Sep. 11, 2008, the entire contents of which are incorporated herein by reference.

### BACKGROUND

(a) Technical Field

The present disclosure relates to an organic light emitting device and a manufacturing method thereof.

(b) Discussion of Related Art

Exemplary embodiments of the present invention relate to an organic light emitting device and a manufacturing method thereof.

Currently, as demand for lighter or thinner monitors and TVs is increasing, cathode ray tubes (CRTs) are being replaced by liquid crystal displays (LCDs).

Because the LCD is a passive display device, however, an additional back-light as a light source is needed, and the LCD has various problems such as a slow response speed and a narrow viewing angle.

Among the flat panel displays, an organic light emitting device (organic light emitting diode display, OLED display) has recently been the most promising as a display device for solving these problems.

The organic light emitting device includes two electrodes and an organic light emitting layer interposed between the two electrodes. One of the two electrodes injects holes and the other injects electrons into the light emitting layer. The injected electrons and holes are combined to form excitons and the excitons emit light as discharge energy.

Because the organic light emitting device is a self-emissive display device, an additional light source is not necessary such that the organic light emitting device has lower power consumption, as well as a high response speed, wide viewing angle, and high contrast ratio.

The OLED may be classified as a passive matrix OLED or an active matrix OLED, according to a driving type.

The passive organic light emitting diode display has a simple structure where light is emitted from a region where the two electrodes cross each other. The active organic light emitting diode display has a structure where light is emitted through current-driving by a thin film transistor (TFT) for each pixel.

According to the light emitting structure, the active organic light emitting diode display is divided into a bottom emission structure where light is emitted toward a substrate on which thin film transistors are formed, and a top emission structure where light is emitted from a side opposite to the substrate on which the thin film transistors are formed.

In the bottom emission structure, the light is transmitted at the portion where the thin film transistor and the wiring are formed, such that the aperture ratio is low, however, the light emitting region of the top emission structure is independent of the area occupied by the thin film transistor and the wiring, such that the aperture ratio is high. Accordingly, the organic light emitting device of the top emission structure is free from the design and the disposition of the thin film transistor and may obtain the high aperture ratio.

The light emitted from the organic light emitting device, however, is passed through several layers having different refractive indexes, such that a light scattering effect is generated by the different refractive indexes. The light scattering effect deteriorates the brightness and light efficiency of the organic light emitting device. As a result, high power consumption is required for high luminance light emission. Also, the luminance of the emitted light is not uniformly reduced at viewing angles for each color R, G and B, such that there is a problem in that the viewing angle is deteriorated.

The above information disclosed in this Background section is only for enhancement of understanding of the background of the invention and, therefore, it may contain information that does not form the prior art that is already known in this country to a person of ordinary skill in the art.

### SUMMARY OF THE INVENTION

Exemplary Embodiments of the present invention improve the light efficiency of the viewing angle characteristic of the organic light emitting device of the top emission structure.

An organic light emitting device according to an exemplary embodiment of the present invention includes: a first substrate; a plurality of thin film transistors formed on the first substrate; an insulating layer formed on the thin film transistors; a pixel electrode formed on the insulating layer, and connected to one of the thin film transistors; an organic light emitting member formed on the pixel electrode; a common electrode formed on the organic light emitting member; a connection member formed on the common electrode; and a color filter formed corresponding to the organic light emitting member on the connection member and including a groove.

The groove of each color filter may have a concave lens shape.

The grooves with the concave lens shape may be formed at uniform intervals and with a uniform size in the color filter.

Neighboring grooves with the concave lens shape may contact each other.

The groove of each color filter may have a pillar configuration.

The pillar configuration groove may have a square pillar shape.

The surface of the color filter including the groove may be uneven.

The color filter may be made of a photosensitive material.

The color filter may be formed through a mask having a slit pattern at a position corresponding to the groove with the concave lens shape.

The connection member may be an epoxy resin.

The refractive index of the epoxy resin may be larger than the refractive index of the color filter.

The pixel electrode may be made of a reflective material, and the common electrode may be made of a translucent material.

The common electrode may have a thickness of 50 to 300 Å, and includes at least one of silver (Ag) and magnesium (Mg).

The organic light emitting device may further include a black matrix disposed on the color filter, and has an opening corresponding to the region of the color filter.

The organic light emitting device may further include a second substrate disposed on the black matrix.

The first substrate may further include a gate line, a data line, and a driving voltage fine, the thin film transistors include switching transistors and driving transistors, and the switching transistors and the driving transistors are disposed for every pixel area defined by the gate line and the data line.

The gate line and the data line are connected to the switching transistor, and the driving voltage line is connected to the driving transistor.

The organic light emitting device may further include an auxiliary electrode line transmitting a voltage to the common electrode, and the auxiliary electrode line and the common electrode are electrically connected to each other for every pixel area.

The organic light emitting member may include an emission layer and an auxiliary layer, and the auxiliary may include at least one of an electron transporting layer, a hole transportation layer, an electron injection layer, and a hole injection layer.

The emission layer may emit one color.

The organic light emitting device may further include a partition formed between neighboring organic light emitting members to divide the organic light emitting members of different colors.

The emission layer may include all emission layers respectively emitting red, green, and blue.

A manufacturing method of an organic light emitting device according to an exemplary embodiment of the present invention includes: forming a black matrix having an opening on an insulation substrate; forming a color filter having a groove in the opening; forming a connection member on the color filter; aligning a thin film transistor array panel facing the insulation substrate and including an organic light emitting member; and hardening the connection member.

The groove of the color filter may be made to have a concave lens shape.

The groove of the color filter may be made to have a pillar shape.

The groove with the pillar shape may be made to have a square pillar shape.

The surface of the color filter having the groove may be made uneven.

The groove of the concave lens shape may be formed by using a mask having a slit pattern.

The color filter may be made of a photosensitive material.

The connection member may be made of an epoxy resin.

The organic light emitting member may be aligned to correspond to the color filter.

Accordingly, light efficiency of the organic light emitting device may be improved, and the path of emitted light varied such that the characteristics of the viewing angle may be improved.

### BRIEF DESCRIPTION OF THE DRAWINGS

Exemplary embodiments of the present invention will be understood in more detail from the following descriptions taken in conjunction with the attached drawings.

FIG. 1 is an equivalent circuit diagram of an organic light emitting device according to an exemplary embodiment of the present invention.

FIG. 2 is a layout view of a thin film transistor array panel in an organic light emitting device according to an exemplary embodiment of the present invention.

FIG. 3 and FIG. 4 are cross-sectional views of the thin film transistor array panel of the organic light emitting device shown in FIG. 2 taken along the lines III-III and IV-IV, respectively.

FIG. 5, FIG. 8, FIG. 11, and FIG. 18 are layout views showing intermediate steps in the manufacturing method according to an exemplary embodiment of the present invention of the thin film transistor array panel in the organic light emitting device shown in FIG. 2 to FIG. 4.

FIG. 6 and FIG. 7 are cross-sectional views of the thin film transistor array panel of the organic light emitting device shown in FIG. 5 taken along the lines VI-VI and VII-VII, respectively.

FIG. 9 and FIG. 10 are cross-sectional views of the thin film transistor array panel of the organic light emitting device shown in FIG. 8 taken along the lines IX-IX and X-X, respectively.

FIG. 12 and FIG. 13 are cross-sectional views of the thin film transistor array panel of the organic light emitting device shown in FIG. 11 taken along the lines XII-XII and XIII-XIII, respectively.

FIG. 14 to FIG. 17 are cross-sectional views of the following step of FIG. 11 to FIG. 13.

FIG. 19 and FIG. 20 are cross-sectional views of the thin film transistor array panel of the organic light emitting device shown in FIG. 18 taken along the lines XIX-XIX and XX-XX, respectively.

FIG. 21 is a layout view of a color filter display for an organic fight emitting device according to an exemplary embodiment of the present invention.

FIG. 22 is a cross-sectional view taken along the line XXII-XXII of FIG. 21.

FIG. 23 is a cross-sectional view similar to FIG. 22.

FIG. 24 is a view showing one example of a mask used in manufacturing the display of FIG. 21.

FIG. 25 and FIG. 26 are cross-sectional views taken along the line III-III and IV-IV of FIG. 2 after combining the thin film transistor array panel and the color filter display panel of the organic light emitting device.

FIG. 27 is a view showing a processing direction of the light in the groove of a concave lens shape according to an exemplary embodiment of the present invention.

FIG. 28 and FIG. 29 are cross-sectional views showing an organic light emitting member according to an exemplary embodiment of the present invention.

FIG. 30 and FIG. 31 are cross-sectional views for a color filter display panel for an organic light emitting device according to an exemplary embodiment of the present invention.

### DETAILED DESCRIPTION OF EXEMPLARY EMBODIMENTS

The present invention will be described more fully hereinafter with reference to the accompanying drawings, in which exemplary embodiments of the present invention are shown.

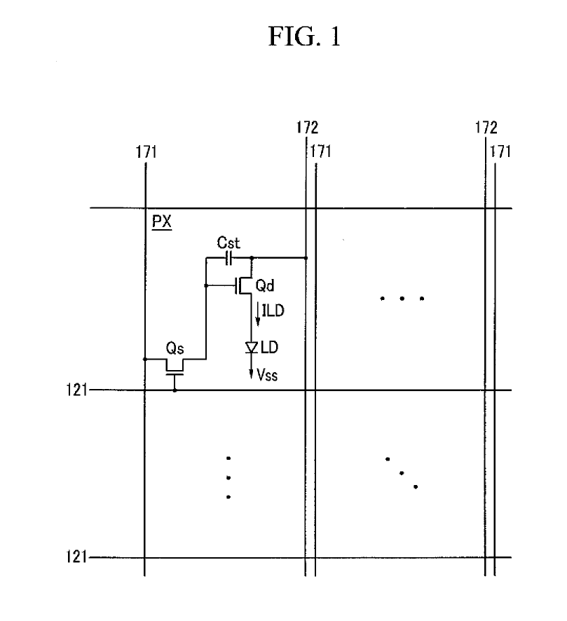

Initially, an organic light emitting device according to an exemplary embodiment of the present invention will be described with reference to FIG. 1.

FIG. 1 is an equivalent circuit diagram of an organic light emitting device according to an exemplary embodiment of the present invention.

Referring to FIG. 1, an organic light emitting device according to the present exemplary embodiment includes a plurality of signal lines 121, 171, and 172, and a plurality of pixels PX connected thereto and arranged substantially in a matrix.

The signal lines include a plurality of gate lines 121 for transmitting gate signals (or scanning signals), a plurality of data lines 171 for transmitting data signals, and a plurality of driving voltage lines 172 for transmitting a driving voltage. The gate lines 121 extend substantially in a row direction and substantially parallel to each other, and the data lines 171 and the driving voltage lines 172 extend substantially in a column direction and substantially parallel to each other.

Each pixel PX includes a switching transistor Qs, a driving transistor Qd, a capacitor Cst, and an organic light emitting diode (OLED) LD.

The switching transistor Qs has a control terminal connected to one of the gate lines 121, an input terminal connected to one of the data lines 171, and an output terminal connected to the driving transistor Qd. The switching transistor Qs transmits the data signals applied to the data line 171 to the driving transistor Qd in response to a gate signal applied to the gate line 121.

The driving transistor Qd has a control terminal connected to the switching transistor Qs, an input terminal connected to the driving voltage line 172, and an output terminal connected to the organic light emitting diode LD. The driving transistor Qd produces an output current ILD having a magnitude depending on the voltage between the control terminal and the output terminal thereof.

The capacitor Cst is connected between the control terminal and the input terminal of the driving transistor Qd. The capacitor Cst stores a data signal applied to the control terminal of the driving transistor Qd and maintains the data signal after the switching transistor Qs turns off.

The organic light emitting diode LD has an anode connected to the output terminal of the driving transistor Qd and a cathode connected to a common voltage Vss. The organic light emitting diode LD emits light having an intensity depending on an output current ILD of the driving transistor Qd, thereby displaying images.

The switching transistor Qs and the driving transistor Qd are n-channel field effect transistors (PETs). At least one of the switching transistor Qs and the driving transistor Qd, however, may be a p-channel FET. In addition, the connections among the transistors Qs and Qd, the capacitor Cst, and the organic light emitting diode LD may be modified.

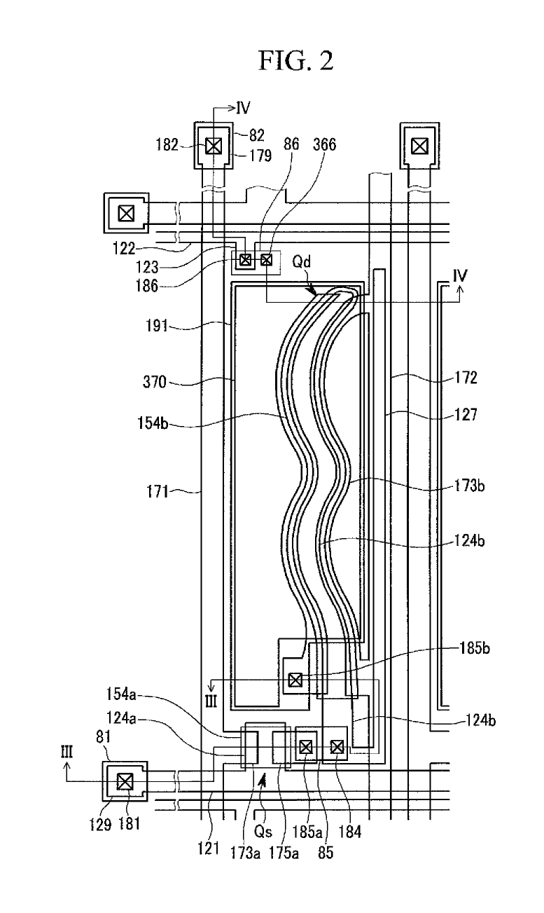

Next, the detailed structure of a thin film transistor array panel for the organic light emitting device shown in FIG. 1 will be described with reference to FIG. 2 to FIG. 4, as well as FIG. 1.

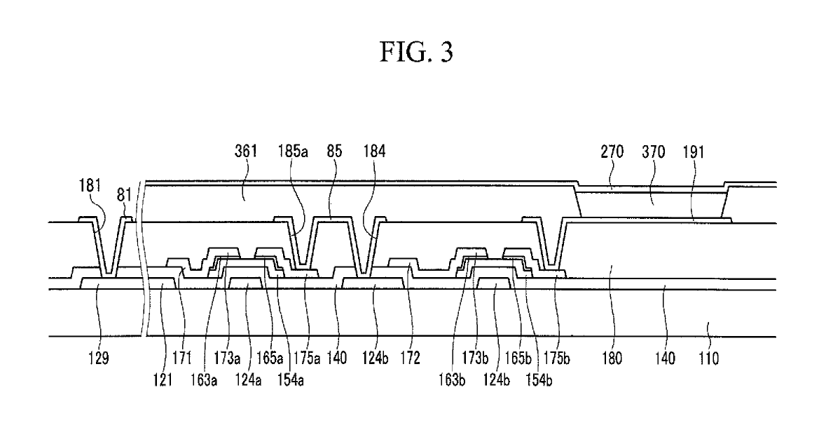

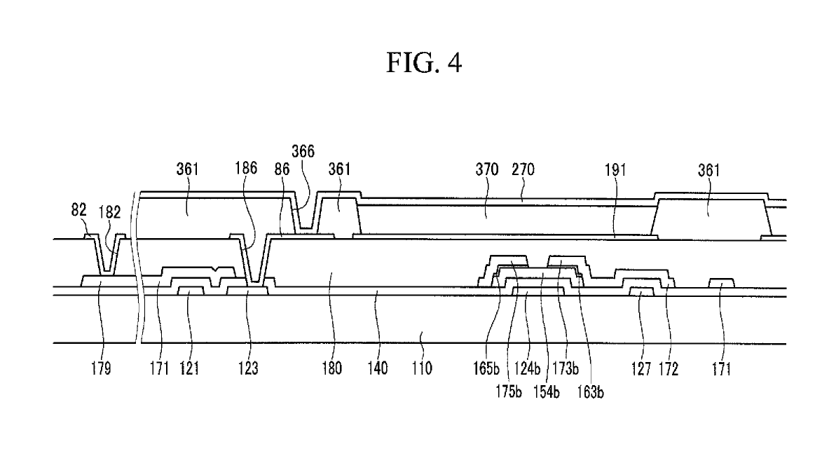

FIG. 2 is a layout view of a thin film transistor array panel in an organic light emitting device according to an exemplary embodiment of the present invention, and FIG. 3 and FIG. 4 are cross-sectional views of the thin film transistor array panel of the organic light emitting device shown in FIG. 2 taken along the lines III-III and IV-IV, respectively.

A plurality of gate conductors including a plurality of gate lines 121 including a plurality of first control electrodes 124a, a plurality of second control electrodes 124b, and an auxiliary electrode line 122 including a protrusion 123 are formed on an insulating substrate 110 that is made of a material such as transparent glass or plastic.

The gate lines 121 transmit gate signals and are substantially extended in the transverse direction. Each gate line 121 includes an end portion 129 having a large area for contact with another layer or an external driving circuit, and the first control electrodes 124a are extended upward from the gate lines 121. When a gate driving circuit (not shown) for generating gate signals is integrated on the substrate 110, the gate lines 121 may be connected to the gate driving circuit.

The second control electrodes 124b are separated from the gate lines 121 and include a storage electrode 127 extending in the downward direction, changing to the right direction, and extending in the upward direction.

The auxiliary electrode line 122 transmits a common voltage and extends parallel to the gate lines 121. The protrusion 123 extends downward from the auxiliary electrode line 122.

Side surfaces of the gate conductors 121, 124b, and 122 are inclined to a surface of the substrate 110, and an inclination angle thereof is preferably about 30° to 80°.

A gate insulating layer 140, which is made of silicon nitride (SiNx), silicon oxide (SiOx), or the like, is formed on the gate conductors 121, 124b, and 122.

A plurality of first and second semiconductor islands 154a and 154b that are made of hydrogenated amorphous silicon (a-Si), polysilicon, or the like, are formed on the gate insulating layer 140. The first semiconductor islands 154a are disposed on the first control electrodes 124a, and the second semiconductor islands 154b are disposed on the second control electrodes 124b.

A plurality of pairs of first ohmic contacts 163a and 165a and a plurality of pairs of second ohmic contact 163b and 165b are formed on the first and second semiconductor islands 154a and 154b, respectively. The ohmic contacts 163a, 163b, 165a, and 165b have an island shape, and are made of a material such as n+ hydrogenated amorphous silicon that is heavily doped with an n-type impurity such as phosphorus.

A plurality of data conductors including a plurality of data lines 171, a plurality of driving voltage lines 172, and a plurality of first and second output electrodes 175a and 175b are formed on the ohmic contacts 163a, 163b, 165a, and 165b, and on the gate insulating layer 140.

The data lines 171 transmit data signals and extend in the longitudinal direction, thereby intersecting the gate lines 121. Each data line 171 includes a plurality of first input electrodes 173a extending toward the first control electrodes 124a and an end portion 179 having a large area for contact with another layer or an external driving circuit When a data driving circuit (not shown) for generating the data signals is integrated on the substrate 110, the data lines 171 may be connected to the data driving circuit.

The driving voltage lines 172 transmit driving voltages and extend in a vertical direction while intersecting the gate lines 121. Each driving voltage line 172 includes a plurality of second input electrodes 173b extending toward the second control electrodes 124b. The driving voltage line 172 overlaps the storage electrode 127.

The first and second output electrodes 175a and 175b are separated from each other, and are separated from the data lines 171 and the driving voltage lines 172. The first input electrodes 173a and the first output electrodes 175a are opposite to each other with respect to the first control electrodes 124a, and the second input electrodes 173b and the second output electrodes 175b are opposite to each other with respect to the second control electrodes 124b.

Instead of the above-described auxiliary electrode line 122, an auxiliary electrode line may be formed with the same layer as the data lines 171, a plurality of the driving voltage lines 172, and a plurality of the first and second output electrodes 175a and 175b. In this case, the auxiliary electrode line may extend in the direction parallel to the data lines 171.

Side surfaces of the data conductors 171, 172, 175a, and 175b are inclined to a surface of the substrate 110, and an inclination angle thereof is preferably about 30° to 80°, like the gate conductors 121, 124b, and 122.

A passivation layer 180 is formed on the data conductors 171, 172, 175a, and 175b, the exposed semiconductors 154a and 154b, and the gate insulating layer 140.

The passivation layer 180 may be made of an inorganic insulator or an organic insulator, and has a flat surface. Examples of the inorganic insulator may be silicon nitride (SiNx) and silicon oxide (SiO2), and an example of the organic insulator may be a polyacryl group compound. The passivation layer 180 may have a dual-layer structure of the organic layer and the inorganic layer.

The passivation layer 180 has a plurality of contact holes 182, 185a, and 185b respectively exposing the end portions 179 of the data lines 171, and the first and second output electrodes 175a and 175b, and the passivation layer 180 and the gate insulating layer 140 have a plurality of contact holes 181, 184, and 186 respectively exposing the end portions 129 of the gate lines 121, the second input electrodes 124b, and the protrusion 123 of the auxiliary electrode line 122.

A plurality of pixel electrodes 191, a plurality of connecting members 85 and 86, and a plurality of contact assistants 81 and 82 are formed on the passivation layer 180 and are made of an opaque conductor for reflecting incident light. The opaque conductor may be made of aluminum or an aluminum alloy, or it may be an opaque conductor having a high work function, such as Au, Pt, Nit Cu, W, or compositions thereof.

The pixel electrodes 191 are physically and electrically connected to the second output electrodes 175b through the contact holes 185b.

The first connecting member 85 is connected to the second control electrode 124b and the first output electrode 175a though the contact holes 184 and 185a, and the second connecting member 86 is connected to the protrusion 123 of the auxiliary electrode line 122 through the contact hole 186.

The contact assistants 81 and 82 are connected to the end 129 of the gate line 121 and the end 129 of the data line 171 through the contact holes 181 and 182, respectively. The contact assistants 81 and 82 complement adhesion to the ends 129 and 179 of the gate line 121 and the data line 171, and protect them.

A partition 361 is formed on the passivation layer 180. The partition 361 defines an opening by surrounding the edges of the pixel electrode 191 like a bank. The partition 361 may be made of an organic insulator having a heat-resisting property and a solvent resistance property, such as acrylic resin and polyimide resin, or may be an inorganic insulator, such as SiO2 and TiO2. Also, the partition 361 may be formed as two or more layers. The partition 361 may be made of a photosensitive material having a black pigment. In is case, the partition 361 functions as a light blocking member, and its manufacturing process isnot complicated.

The partition 361 has a contact hole 366 exposing the second connecting member 86.

An organic light emitting member 370 is formed on the opening that is formed on the pixel electrode 191 and defined by the partition 361.

The organic light emitting member 370 may have a multi-layered structure including an emitting layer (not shown) for emitting light, and an auxiliary layer (not shown) for improving the light emitting efficiency. This will be described in more detail hereinbelow.

A common electrode 270 is formed on the organic light emitting member 370. The common electrode 270 is formed on the entire substrate, and forms a pair with the pixel electrode 191 to cause the current to flow to the organic light emitting member 370.

The common electrode 270 may be made of a conductive material that has a good electron injection property and does not affect the organic material, such as a semi-transparent conductive material. The common electrode 270 may be made of a single layer having a thickness of only about 50 to 300 Å and including aluminum (Al), silver (Ag), magnesium (Mg), or a multi-layer including Mg—Ag, Ca—Ag, LiF—Al, Ca—Ba, Ca—Ag—ITO. The common electrode 270 made of a semi-transparent conductive material is included such that top emission for emitting the light in the upper direction of the substrate 110 having the thin film transistors may be obtained. The semi-transparent common electrode 270 and the opaque pixel electrodes 191 reflecting all light emit the light by using a micro-cavity effect. That is, the light that is reflected between two electrodes is passed through the semi-transparent common electrode 270 and emitted if a predetermined condition is satisfied. In this exemplary embodiment, the transmittance may be controlled by using the characteristics (thickness or material) of the semi-transparent common electrode 270, or the interval, that is, the spacing, between the common electrode 270 and the pixel electrode 191, and may be determined to have a light transmittance of 40 to 60% in an exemplary embodiment of the present invention. When using the micro-cavity effect, the wavelength of the emitted light may be selected such that a spectrum in which the resolution of the color is improved may be obtained. The micro-cavity effect improves resolution of the color, but the light is not emitted with various angles such that the reduction of the luminance is not uniform according to the viewing angle, thereby generating a drawback that the viewing angle is decreased. The drawback that the viewing angle is decreased is solved by forming a groove on the surface of the color filter, which will be described later.

The common electrode 270 is connected to the protrusion 123 of the auxiliary electrode line 122 through the contact hole 366 and the second connecting member 86. In this way, the common electrode 270 is connected to the protrusion of the auxiliary electrode line such that the common electrode 270 may be stably supplied with the common voltage, even though the common electrode 270 for the top emission is made of a transparent or semi-transparent conductive material having relatively large resistance. Accordingly, the voltage drop is not present, and the same common voltage may be transmitted to the whole region of the common electrode 270.

In this organic light emitting device, the switching control electrode 124a electrically connected to the gate line 121, the switching input electrode 173a electrically connected to the data line 171, and the switching output electrode 175a form the switching thin film transistor Qs shown in FIG. 1 along with the switching semiconductor 154a, and the channel of the switching thin film transistor Qs is formed in the switching semiconductor 154a between the switching input electrode 173a and the switching output electrode 175a. The driving control electrode 124b electrically connected to the switching output electrode 175a, the driving input electrode 173b electrically connected to the driving voltage line 172, the driving output electrode 175b electrically connected to the pixel electrode 191, and the driving semiconductor 154b form the driving thin film transistor Qd shown in FIG. 1, and the channel of the driving thin film transistor Qd is formed in the driving semiconductor 154b between the driving input electrode 173b and the driving output electrode 175b.

In the organic light emitting device of the top emission structure according to the present exemplary embodiment, the thin film transistor and the wiring do not affect the aperture ratio, as shown in FIG. 2, such that the width of the channel of the driving transistor is increased to increase the driving current, thereby increasing the luminance.

Although the present exemplary embodiment of FIG. 1 shows only one switching thin film transistor and driving only one thin film transistor, it may further include another thin film transistor and wiring for driving the same, in addition to the switching thin film transistor and the driving thin film transistor, such that degradation of the organic light emitting diode LD and the driving transistor Qd can be prevented or compensated even during long-term driving, making it possible to prevent a reduction in the lifetime of the organic light emitting device.

A pixel electrode 191, the organic light emitting member 370, and the common electrode 270 form the organic light emitting diode LD, and the storage electrode 127 and the driving voltage line 172 overlapping each other form the storage capacitor Cst.

When the semiconductors 154a and 154b are made of polycrystalene silicon, they include an intrinsic region (not shown) facing the control electrode 124a and extrinsic regions (not shown) positioned at both sides thereof. The extrinsic regions are electrically connected with the input electrodes 173a and 173b and the output electrodes 175a and 175b, and the ohmic contacts 163a, 163b, 165a, and 165b can be omitted.

The control electrodes 124a and 124b may be positioned on the semiconductors 154a and 154b, and also in is case, the gate insulating layer 140 is positioned between the semiconductors 154a and 154b and the control electrodes 124a and 124b. The data conductors 171, 172, 173b, and 175b can be positioned on the gate insulating layer 140 and electrically connected with the semiconductors 154a and 154b via contact holes (not shown) formed at the gate insulating layer 140. Alternatively, the data conductors 171, 172, 173b, and 175b can be positioned below the semiconductors 154a and 154b so as to electrically contact the upper semiconductors 154a and 154b.

A color filter display panel is formed on the common electrode 270, and will be described hereinbelow.

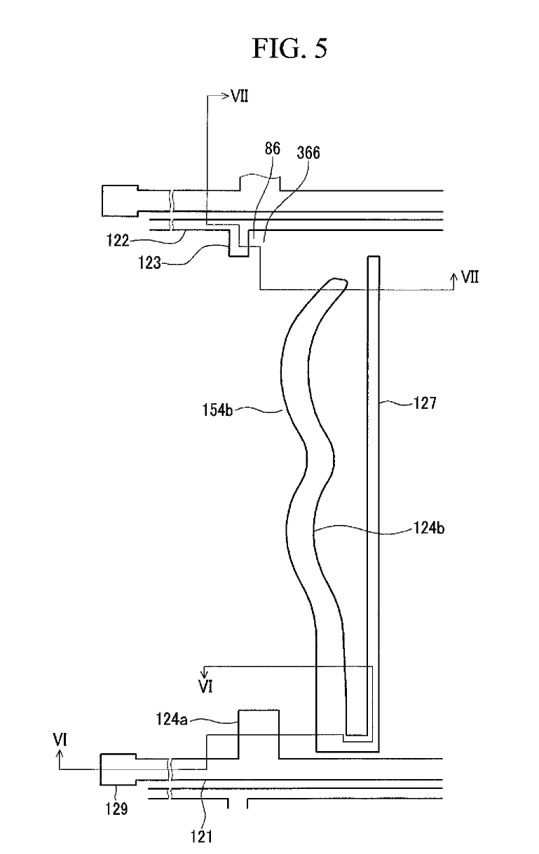

The manufacturing method of the OLED of FIG. 2 to FIG. 5 according to an exemplary embodiment of the present invention will now be described in detail with reference to FIGS. 5 to 23.

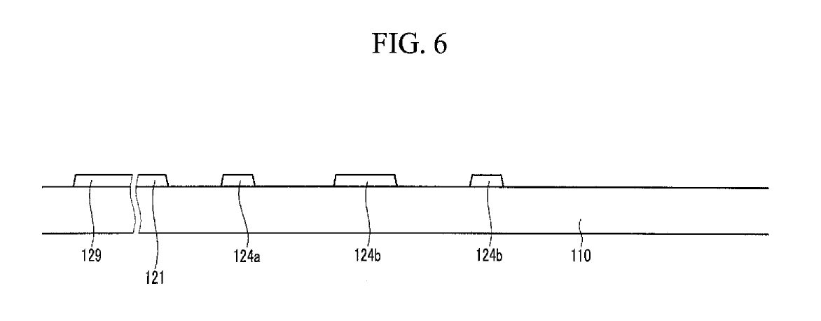

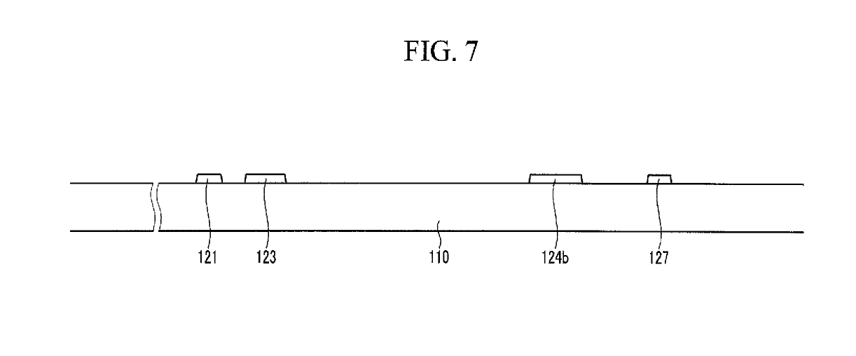

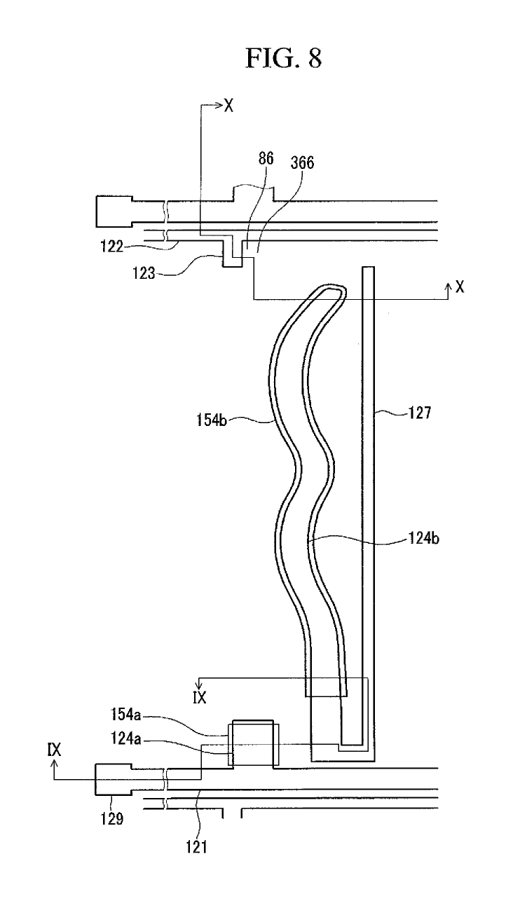

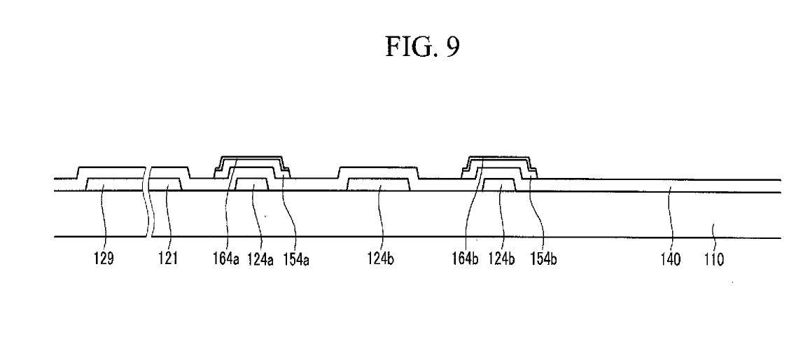

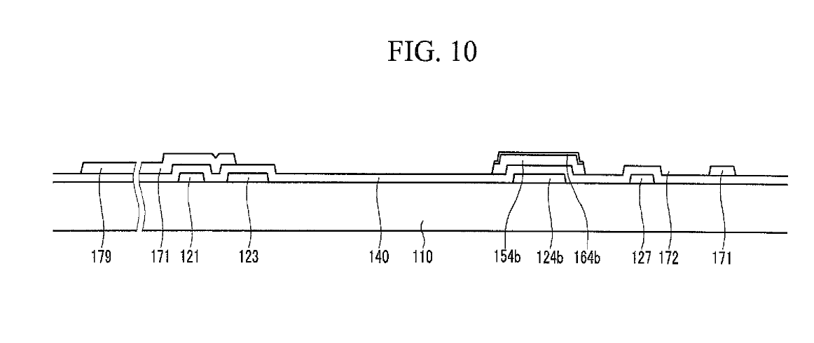

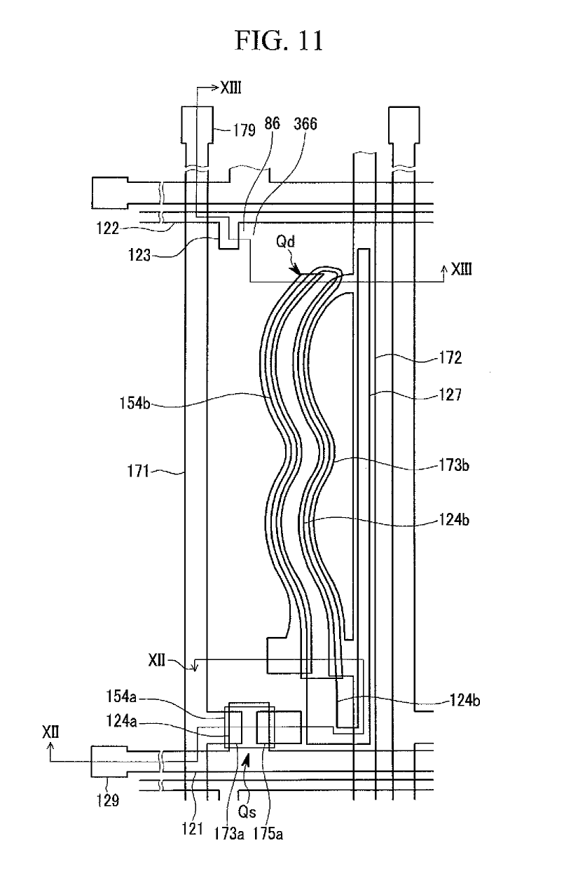

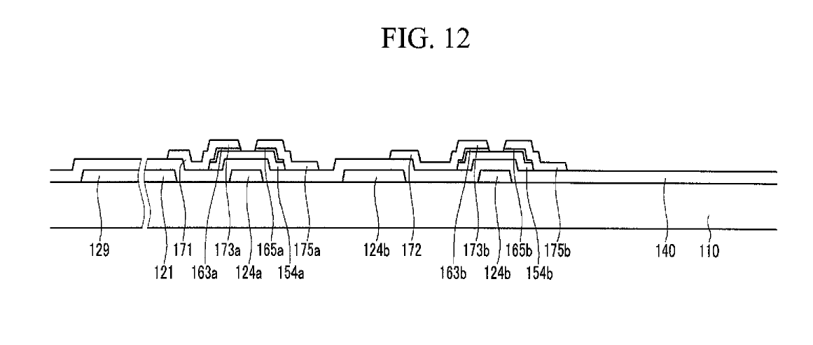

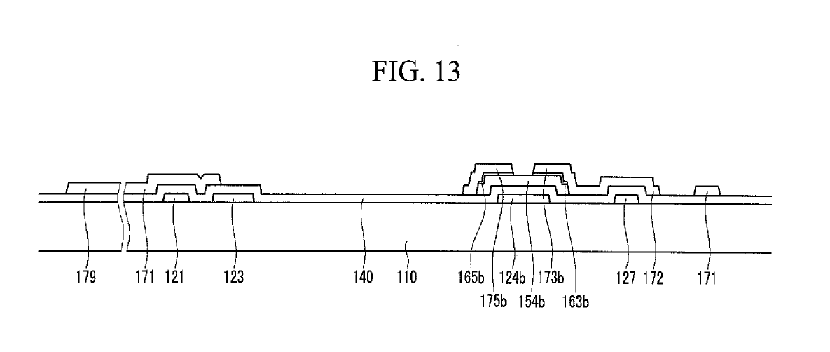

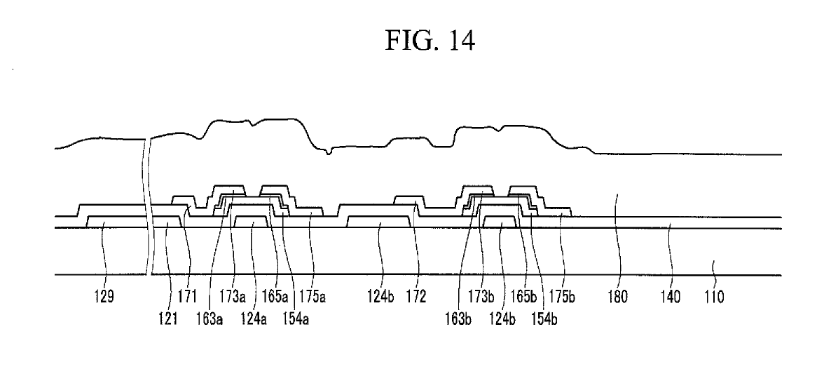

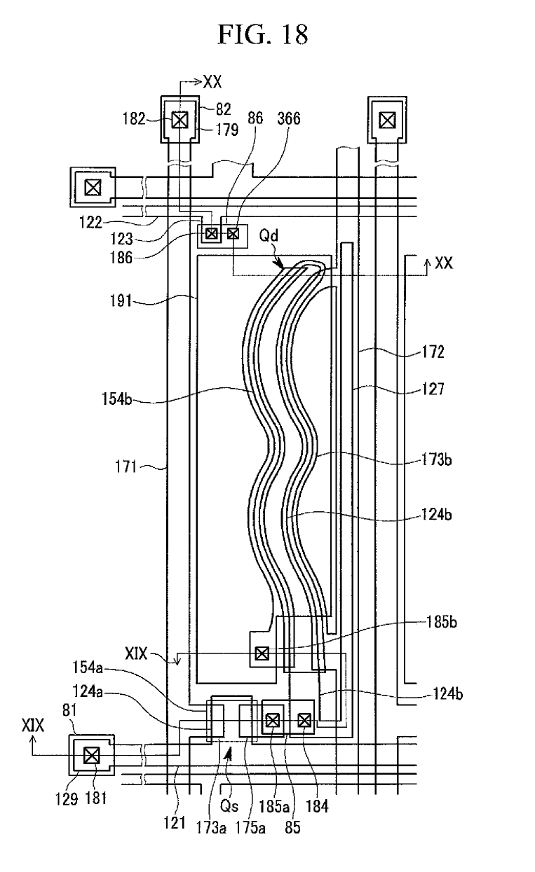

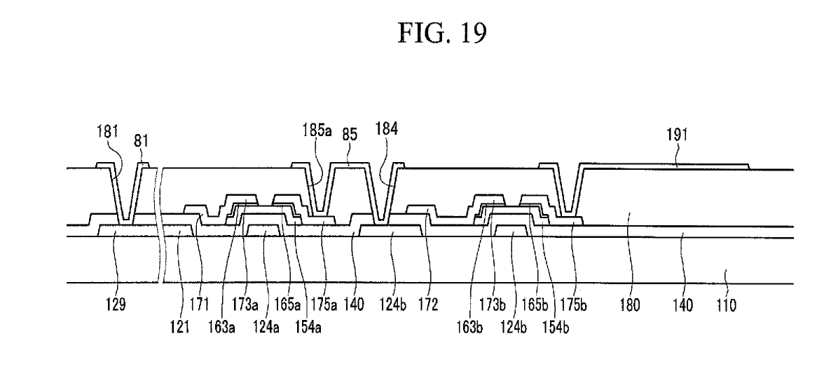

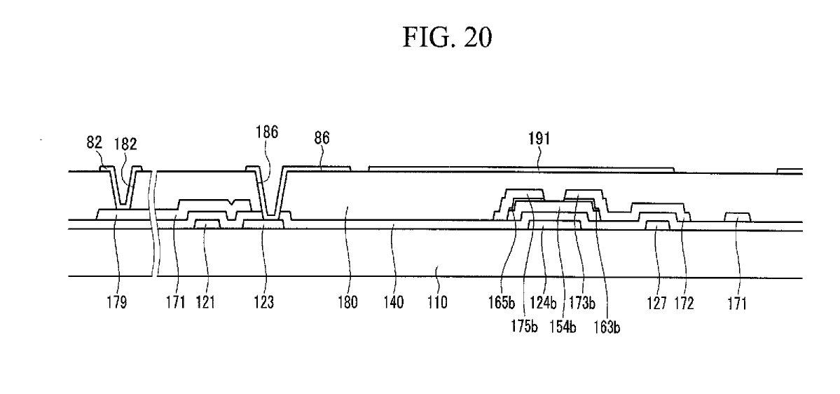

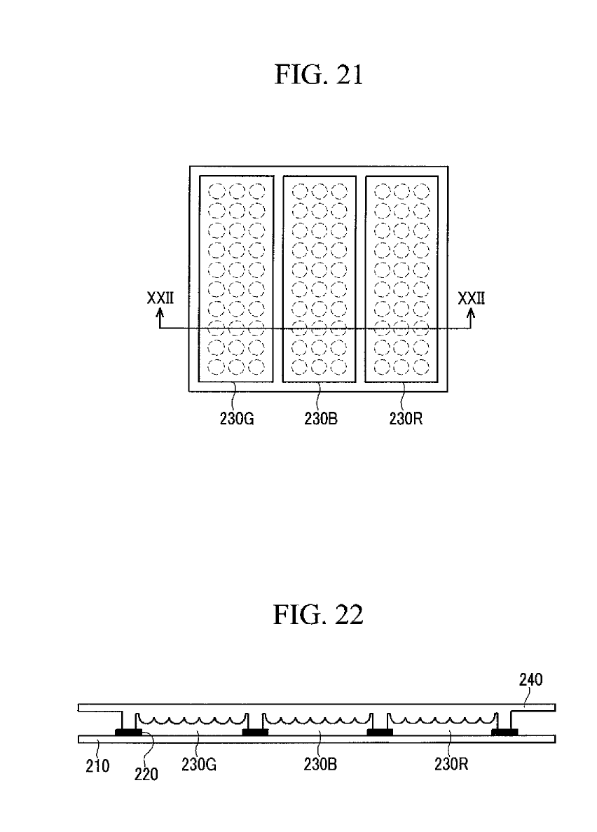

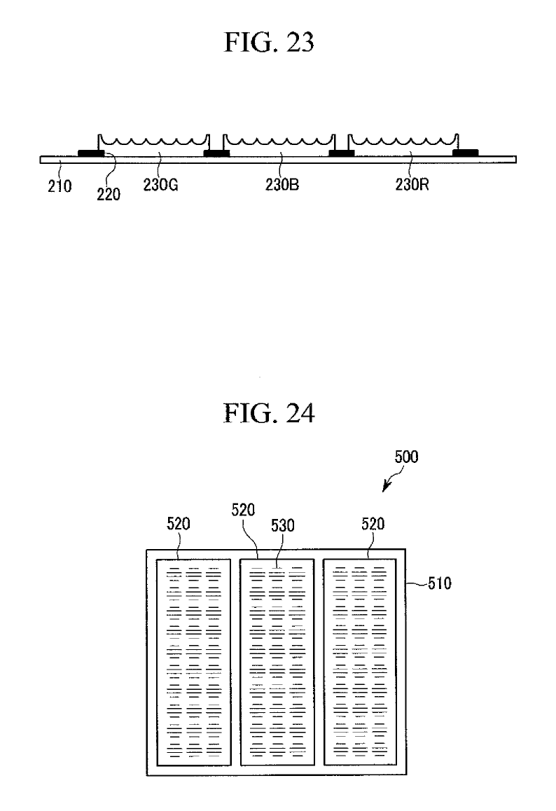

FIG. 5, FIG. 8, FIG. 11, and FIG. 18 are layout views showing the middle steps in the manufacturing method according to an exemplary embodiment of the present invention of the thin film transistor array panel in the organic light emitting device shown in FIG. 2 to FIG. 4; FIG. 6 and FIG. 7 are cross-sectional views of the thin film transistor array panel of the organic light emitting device shown in FIG. 5 taken along the lines VI-VI and VII-VII; FIG. 9 and FIG. 10 are cross-sectional views of the thin film transistor array panel of the organic light emitting device shown in FIG. 8 taken along the lines IX-IX and X-X; FIG. 12 and FIG. 13 are cross-sectional views of the thin film transistor array panel of the organic light emitting device shown in FIG. 11 taken along the lines XII-XII and XIII-XIII; FIG. 14 to FIG. 17 are cross-sectional views of the device following the steps of FIG. 11 to FIG. 13; FIG. 19 and FIG. 20 are cross-sectional views of the thin film transistor array panel of the organic light emitting device shown in FIG. 18 taken along the lines XIX-XIX and XX-XX; FIG. 21 is a layout view of a color filter display for an organic light emitting device according to an exemplary embodiment of the present invention; FIG. 22 is a cross-sectional view taken along the line XXII-XXII of FIG. 21; and FIG. 23 is a cross-sectional view of an organic light emitting device according to an exemplary embodiment of the present invention,

As shown in FIG. 5 to FIG. 7, the gate conductors, which are made of an aluminum alloy and include the plurality of gate lines 121 including the first control electrode 124a and the end portion 129, a plurality of second control electrodes 124b including the storage electrode 127, and an auxiliary electrode line 122 including a protrusion 123 are formed on the transparent insulation substrate 110.

Next, as shown in FIG. 8 to FIG. 10, triple layers of the gate insulating layer 140, the intrinsic amorphous silicon layer, and an impurity amorphous silicon layer are successively stacked, and then the impurity amorphous silicon layer and the intrinsic amorphous silicon layer are processed through photolithography to form a plurality of first and second impurity semiconductors 164a and 164b and a plurality of first and second semiconductor islands 154a and 154b.

Subsequently, as shown in FIG. 11 to FIG. 13, the data conductors, which are made of the aluminum alloy and include the plurality of data lines 171 including the first input electrode 173a and the end portion 179 and the driving voltage line 172 including the second input electrode 173b, and the plurality of first and second output electrodes 175a and 175b are formed.

Thereafter, the impurity semiconductor portions 164a and 164b shown in FIG. 9 that are exposed without being covered by the data conductors 171, 172, 175a, and 175b are removed to complete the ohmic contacts 163a, 165a, 163b, and 165b and expose a portion of the lower first and second semiconductors 154a and 154b.

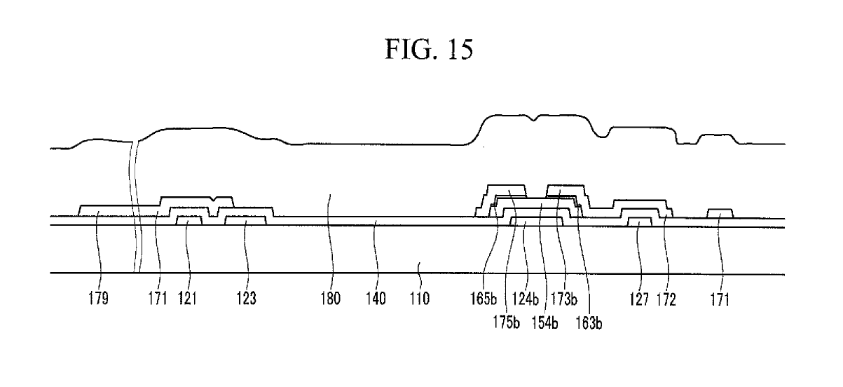

Next, as shown in FIG. 14 and FIG. 15, a passivation layer 180 is formed by using chemical vapor deposition or printing. In this exemplary embodiment, the surface of the passivation layer 180 may be formed to be uneven according to the different thicknesses of the lower patterns, such as the gate lines, the data lines, and the thin film transistor.

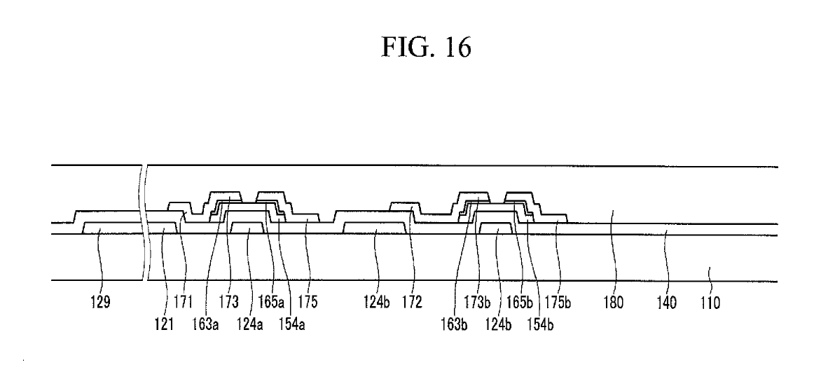

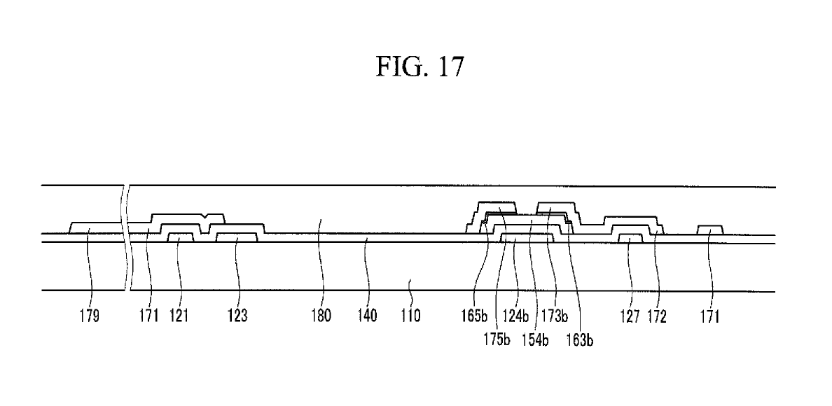

Then, as shown in FIG. 16 and FIG. 17, the uneven surface of the passivation layer 180 may be planarized by using chemical mechanical polishing (CMP). The planarization process may be omitted according to an exemplary embodiment.

Thereafter, as shown in FIG. 18 to FIG. 20, the passivation layer 180 is patterned by photolithography to form a plurality of contact holes 181, 182, 184, 185a, 185b, and 186. The contact holes 181, 182, 184, 185a, 185b, and 186 expose the end portion 129 of the gate line, the end portion 179 of the data line, the second control electrode 124b, the first output electrode 175b, the second output electrode 175b, and the protrusion 123 of the auxiliary electrode line 122.

Next, a plurality of pixel electrodes 191, a plurality of first and second connecting members 85 and 86, and a plurality of contact assistants 81 and 82 are formed on the passivation layer 180.

Then, as shown in FIG. 2 to FIG. 4, a photosensitive organic insulator is coated by using spin coating, and is exposed and developed to form a partition 361 having openings and contact holes 366 on the pixel electrodes 191.

Next, a light emitting member 370 shown in FIGS. 2 to 4 including a hole transporting layer (not shown) and an emission layer (not shown) is formed in the openings disposed on the pixel electrodes 191. The organic light emitting member 370 may be made by a solution process, such as Inkjet printing, in which an Inkjet head (not shown) is moved and a solution is sprayed in the opening, and a drying process is required after forming each layer.

Next, a common electrode 270 shown in FIGS. 2 to 4 is formed on the partition 361 and the organic light emitting member 370.

The thin film transistor array panel for the organic light emitting device is therefore formed as described above.

A color filter display panel for the organic light emitting device will be now described hereinbelow.

FIG. 21 is a plan view of a color filter display having the aforementioned grooves for an organic light emitting device according to an exemplary embodiment of the present invention, and FIG. 22 is a cross-sectional view taken along the line XXII-XXII of FIG. 21.

As shown in FIG. 21 and FIG. 22, in a color filter display panel an insulation substrate 210, a black matrix 220, color filters 230R, 230G, and 230B, and an epoxy resin 240 are formed.

The black matrix 220 having openings therein is formed on the insulation substrate 210.

The color filters 230R, 230G, and 230B are formed in the openings of the black matrix 220, and grooves having a concave lens shape are formed on the respective surface of each of the color filters 230R, 230G, and 230B.

The grooves or indentations having the concave lens shape shown in FIG. 22 are indicated by dotted circles in FIG. 21, and are formed with uniform size and intervals in the surface of each color filter 230R, 230G, and 230B. Nevertheless, a radius or curvature of the grooves having the concave lens shape, as well as the number of grooves, may be variously changed according to an exemplary embodiment.

The epoxy resin 240 covers the black matrix 220 and the color filters 230R, 230G, and 230B, and functions to form a composite of the thin film transistor array panel and the color filter display panel. The epoxy resin 240 is hardened by UV irradiation or a heat treatment thereby fixing the thin film transistor array panel and the color filter display panel into a unit. On the other hand, when fixing two display panels together, a method in which the thin film transistor array panel and the color filter display panel are aligned after half-hardening the epoxy resin 240 may be used, after which the epoxy resin 240 is completely hardened.

The epoxy resin 240 may be replaced with a thermal hardening or a photo-hardening organic material according to the exemplary embodiment, and may include urea resins, melamine resins, phenol resins, epoxy resins, saturated or unsaturated polyester resins, polyurethane resins, acrylic resins, vinyl acetate resins, ethylene-vinyl acetate copolymer resins, polyvinyl alcohol resins, polyamide resins, polyolefin resins, and cellulose.

FIG. 23 is a cross-sectional view showing an intermediate step in a manufacturing method of a color filter display panel for an organic light emitting device according to an exemplary embodiment of the present invention, and FIG. 24 is a view showing one example of a mask used in forming the step of FIG. 23.

FIG. 23 shows the intermediate step for forming a color filter that is at the core in the manufacturing method of a color filter display panel according to an exemplary embodiment of the present invention.

In the manufacturing method of a color filter display panel according to an exemplary embodiment of the present invention, the black matrix 220 is formed on the substrate 210. To form the black matrix 220, a chromium (Cr) layer or a chromium oxide (CrOx) layer is deposited on the substrate and patterned by photolithography to form a plurality of openings or spaces.

Next, color filters 230R, 230G, and 230B are formed in each of the openings for each color. The color filters 230R, 230G, and 230B are comprised of a material having photosensitivity and are formed through a coating or Inkjet method. Although not shown in FIG. 23, initially the upper surfaces of the color filters 230R, 230G, and 230B that are formed through this method are flat, and both sides of the color filters 230R, 230G, and 230B overlap a portion of the black matrix 220. The color filters 230R, 230G, and 230B may have a thickness of several μm, and preferably less than 3 μm. When the light is passed through the color filters 230R, 230G, and 230B, a loss is generated such that it is preferable that the color filter is thinly formed with only a thickness of several μm to reduce the loss.

Next the color filters 230R, 230G, and 230B are exposed by using a mask 500 shown in FIG. 24. As shown in FIG. 24, the mask 500 has a slit pattern 530. Light is irradiated on the flat upper surface of the color filters 230R, 230G, and 230B trough the slit pattern 530, and the corresponding portion is removed upon developing due to the irradiated light. As a result, grooves with a concave lens shape as shown in FIG. 23 are formed.

In this exemplary embodiment, the light irradiation process is separately applied to each color to form the grooves with the concave lens shape, alternatively the same process may be applied for all color filters.

The mask 500 includes regions 520 corresponding to the color filters 230G, 230B, and 230R and a region 510 corresponding to the black matrix 220 that is disposed outside of the slit pattern 530. According to the characteristic of the material forming the color filter, one region is made of the opening for the light to be transmitted, and another region is formed for the light to be blocked. There is a difference according to whether the color filters 230G, 230B, and 230R have a positive photosensitivity or negative photosensitivity.

When the color filters 230G, 230B, and 230R have a positive photosensitivity, the regions 520 corresponding to the color filters are formed to block the light, and the region corresponding to the black matrix 220 is formed to transmit the light.

When the color filters 230G, 230B, and 230R have a negative photosensitivity, the regions 520 corresponding to the color filters are formed to transmit the light, and the region corresponding to the black matrix 220 is formed to block the light. In this exemplary embodiment, the slit pattern 530 may block a portion of the light.

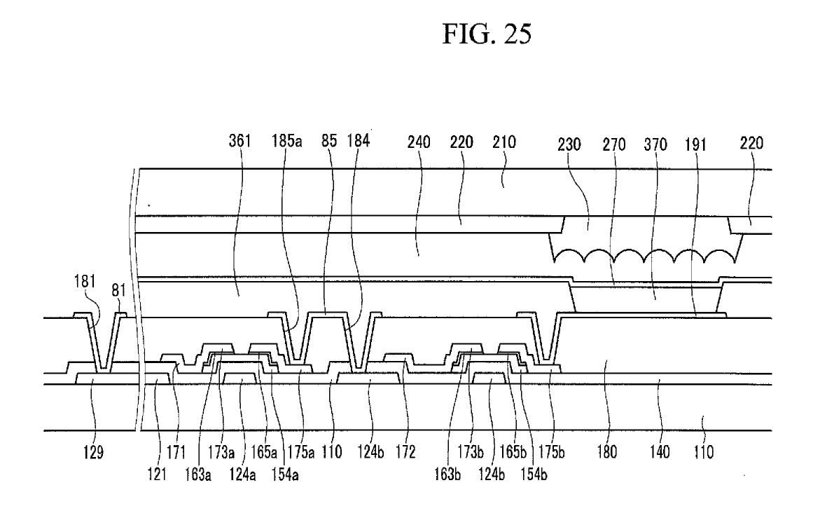

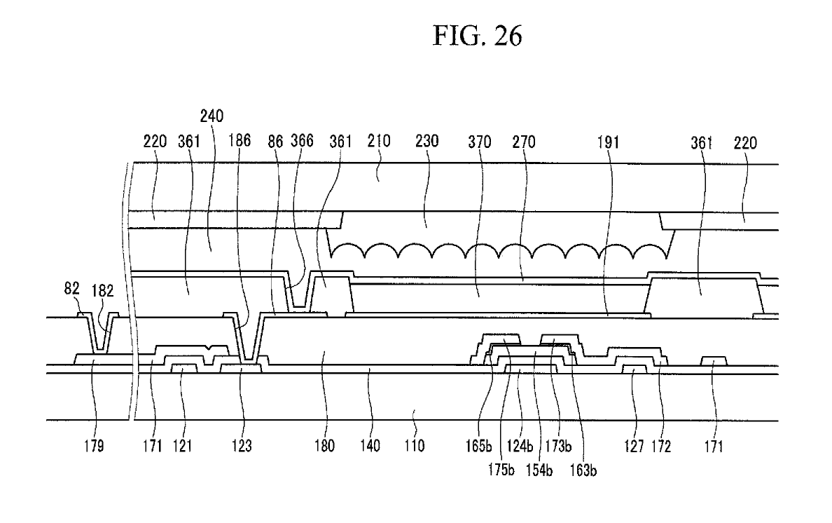

FIG. 25 and FIG. 26 are cross-sectional views taken respectively along the line III-III and the line IV-IV of FIG. 2 after combining the thin film transistor array panel and the color filter display panel of the organic light emitting device.

The thin film transistor array panel and the color filter display panel are aligned and combined so that the color filter 230 and the organic light emitting member 370 correspond in location. The alignment of the color filter display panel and the in film transistor array panel is completed with alignment keys (not shown) respectively formed in the insulation substrates 110 and 210. Next, the epoxy resin 240 is hardened by UV irradiation or heat treatment such that the color filter display panel and the thin film transistor array panel are adhered and fixed together. The epoxy resin 240 is tightly formed on the grooves of the concave lens shape of the color filters such that a space that could be present between the color filter display panel and the common electrode 270 may be eliminated, and the elements may be solidly combined to each other.

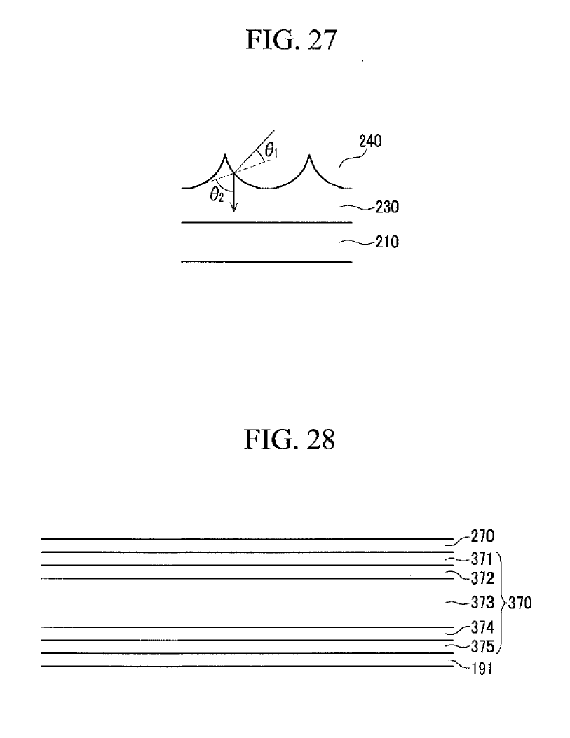

FIG. 27 is a view showing a processing direction of light in the groove of a concave lens shape according to an exemplary embodiment of the present invention.

In FIG. 27, the thin film transistor array panel is disposed in the upper side, and the light is emitted through the lower side, unlike the orientation shown in FIGS. 25 and 26. The light emitted from the organic light emitting member 370 passes the epoxy resin 240 and is incident to the color filter 230. The light that is affected by the micro-cavity effect has the drawback that the side progressing component is decreased, however the grooves of the concave lens shape refract the light to be emitted in various directions. More specifically, a difference exists between refractive indexes of the epoxy resin 240 and the color filter 230 such that an improved viewing angle characteristic may be obtained and, in an exemplary embodiment of the present invention, it is possible for the refractive index of the color filter 230 to be smaller than the refractive index of the epoxy resin 240. That is, referring to FIG. 27, the angle θ1 of which the light is incident to the color filter 230 is smaller than the angle θ2 of which light is bent on the color filter, such that the refractive index of the color filter 230 may be small.

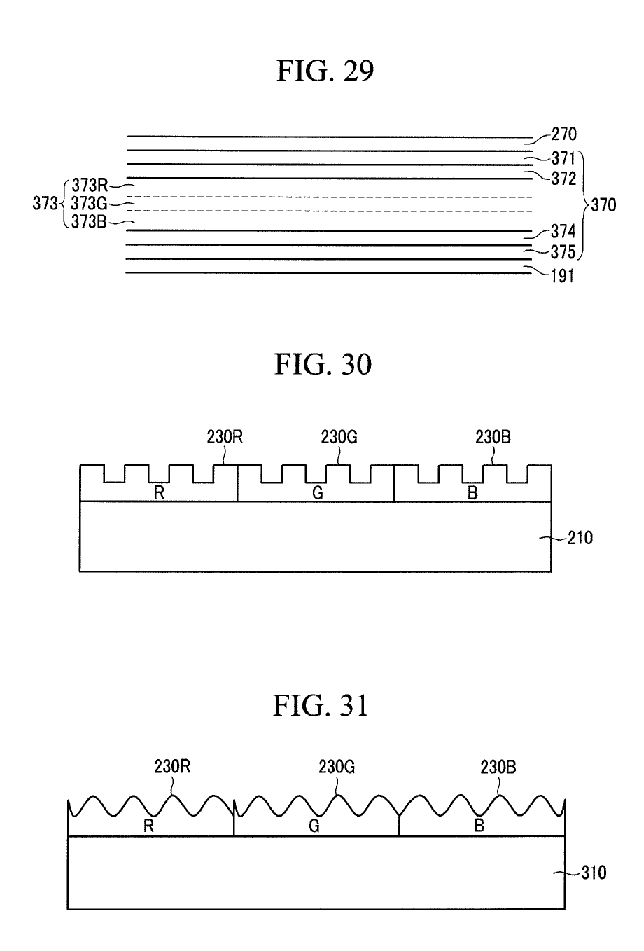

FIG. 28 and FIG. 29 are cross-sectional views showing an organic light emitting member according to an exemplary embodiment of the present invention.

FIG. 28 shows the organic light emitting member emitting only one color light among R, G, B, and FIG. 29 shows the organic light emitting member emitting a white color light.

Firstly, the organic light emitting member 370 is disposed between the pixel electrode 191 shown in FIGS. 25 and 26 that is made of a reflective material and the common electrode 270 that is made of a translucent material.

As shown in FIGS. 28 and 29, the organic light emitting member 370 includes an emission layer 373 and auxiliary layers 371, 372, 374, and 375.

The auxiliary layers include a hole transport layer 372 and an electron transport layer 374 for controlling the balance of electrons and holes, a hole injecting layer 371 and an electron injecting layer 375 for enhancing the injection of electrons and holes, however, one or two selected therefrom may be omitted.

On the other hand, the emission layer 373 may be made of an organic material uniquely emitting one color among the primary colors of red, green, and blue, or a mixture of the organic material and an inorganic material.

In FIG. 28, only one layer is used as the light emission layer 373 to emit one color of red, green, and blue. In contrast, in FIG. 29, three emission layers 373R, 373G, and 373B of red, green and blue are used as the emission layer 373 to emit the white color. Although not shown in FIG. 29, an interlayer may be disposed between each of the emission layers 373R, 373G, and 373B. Also, the emission layers 373R, 373G, and 373B may be double-overlapped to form one emission layer 373.

In the case shown in FIG. 29, it is preferable that a partition does not exist and the organic light emitting member 370 is formed for the whole substrate. In this exemplary embodiment, the connection between the common electrode 270 and the protrusion 123 of the auxiliary electrode line 122 may not be easily made, and the organic light emitting member 370 corresponding to the connection portion may be removed by the irradiation of plasma to make the connection.

As described above, exemplary embodiments of the present invention may use the single organic emission layer 373 of FIG. 28, or the composite organic emission layer 373 of FIG. 29. In the exemplary embodiment using the single organic emission layer 373 of FIG. 28, the color emitted from the organic emission layer 373 must be in accord with the color of the color filter 230. In the case of using the single organic emission layer 373 of FIG. 28, the organic emission layer 373 and the color filter 230 compensate the drawbacks of each other while executing different functions. That is, a color having a known spectrum shape is emitted by using the micro-cavity effect in the organic emission layer 373, and the color filter 230 enforces the color impression and passes the light in the various angles to thereby improve the viewing angle and improve the characteristics of the organic light emitting device.

On the other hand, in the case of using the composite organic emission layer 373 of FIG. 29, provision of the color impression and improvement of the viewing angle are executed in the color filter 230.

FIG. 30 and FIG. 31 are cross-sectional views for a color filter display panel for an organic light emitting device according to an exemplary embodiment of the present invention.

In FIG. 22 and FIG. 23, the exemplary embodiment has the color filters 230R, 230G, and 230B including the grooves with the concave lens shape, however, an exemplary embodiment in which the light is guided in the side direction by using a different structure is shown in FIG. 30 and FIG. 31. In FIG. 30 and FIG. 31, the black matrix 220 is not used, unlike what is shown in FIGS. 22 and 23. The case in which the black matrix 220 is omitted between the color filters 230R, 230G, and 230B is shown in FIG. 30 and FIG. 31.

Initially, the exemplary embodiment of FIG. 30 will be described.

In FIG. 30, the color filters 230R, 230G, and 230B having squarish grooves are shown. In FIG. 30, the structure in which a square pillar configuration is formed among the grooves is shown. The groove with the square pillar configuration has a lower surface on the surface of the color filters 230R, 230G, and 230B, and the lower surface has a rectangle or square configuration. The groove with the square pillar configuration is shown in FIG. 30, alternatively the groove may have various pillar configurations such as a cylinder, a triangular pillar, or a pentagonal pillar.

In FIG. 30, various methods for forming the pillars may be employed. That is, like the method for forming the grooves with the concave lens of FIG. 21, a mask including a slit pattern may be used and a mask of the translucent type may be used. Also, a color filter of a square pattern is firstly formed, and a color filter having the same thickness such that the height of the position where the square pattern is disposed is increased, and the height of the position where the square pattern does not exist is low, to thereby form the grooves with the pillar configuration.

On the other hand, a structure in which the surface of the color filters 230R, 230G, and 230B is uneven or rugged is shown in FIG. 31. As shown in FIG. 31, the highest point and the lowest point may be repeated with uniform intervals and uniform periods. Also, the uneven or rugged surface of FIG. 31 is extended in all directions with reference to the one highest point of FIG. 22.

Like the exemplary embodiment of FIG. 30, a mask including a slit pattern may be used or a mask of the translucent type may be used to form the structure of FIG. 31.

The color filter display panels of FIG. 30 and FIG. 31 may include the epoxy resin, like the color filter display panel of FIG. 25 and FIG. 26.

Exemplary embodiments of the present invention may be applied to a top emission organic light emitting device as well as the structure of FIG. 2 to FIG. 20.

While this invention has been described in connection with what is presently considered to be practical exemplary embodiments, it is to be understood that the invention is not limited to the disclosed exemplary embodiments, but, on the contrary, is intended to cover various modifications and equivalent arrangements included within the spirit and scope of the appended claims.

What is claimed is:

1. An organic light emitting device comprising:
a first substrate;
a plurality of thin film transistors disposed on the first substrate;
an insulating layer disposed on the plurality of thin film transistors;
a pixel electrode disposed on the insulating layer, and connected to one of the thin film transistors;
an organic light emitting member disposed on the pixel electrode;
a common electrode disposed on the organic light emitting member;
a connection member disposed on the common electrode; and
a color filter arranged corresponding to the organic light emitting member and on the connection member, wherein the color filter includes a plurality of grooves.

2. The organic light emitting device of claim 1, wherein
each groove of the color filter has a concave lens shape.

3. The organic light emitting device of claim 2, wherein
the grooves with the concave lens shape are formed at uniform intervals and with a uniform size in the color filter.

4. The organic light emitting device of claim 3, wherein
neighboring grooves with the concave lens shape contact each other.

5. The organic light emitting device of claim 1, wherein
the grooves of the color filter form a pillar configuration.

6. The organic light emitting device of claim 5, wherein
the pillar configuration has a square pillar shape.

7. The organic light emitting device of claim 1, wherein
the surface of the color filter including the grooves is uneven.

8. The organic light emitting device of claim 1, wherein
the connection member is an epoxy resin.

9. The organic light emitting device of claim 1, wherein
the pixel electrode is made of a reflective material, and
the common electrode is made of a translucent material.

10. The organic light emitting device of claim 9, wherein
the common electrode has a thickness of 50 to 300 Å, and includes at least one of silver (Ag) and magnesium (Mg).

11. The organic light emitting device of claim 1, further comprising
a black matrix disposed on the color filter, and having an opening corresponding to the region of the color filter.

12. The organic light emitting device of claim 1, wherein:
the first substrate further includes a gate line, a data line, and a driving voltage line;
the plurality of thin film transistors includes switching transistors and driving transistors; and
the switching transistors and the driving transistors are disposed for every pixel area defined by the gate line and the data line.

13. The organic light emitting device of claim 12, further comprising
an auxiliary electrode line transmitting a voltage to a common electrode,
wherein the auxiliary electrode line and the common electrode are electrically connected to each other for every pixel area.

14. The organic light emitting device of claim 1, wherein
the organic light emitting member includes an emission layer and an auxiliary layer, and the auxiliary includes at least one of an electron transporting layer, a hole transportation layer, an electron injection layer, and a hole injection layer.

15. The organic light emitting device of claim 1, farther comprising:
a plurality of organic light emitting members; and
a partition disposed between neighboring organic light emitting members to divide the organic light emitting members of different colors.

16. A method for manufacturing an organic light emitting device comprising:
forming a black matrix having an opening on an insulation substrate;
forming a color filter having grooves in the opening;
forming a connection member on the color filter;
aligning a thin film transistor array panel facing the insulation substrate and including an organic light emitting member; and
hardening the connection member.

17. The method of claim 16, wherein
the groove of the color filter has a concave lens shape.

18. The method of claim 16, wherein
the surface of the color filter having the grooves is uneven.

19. The method of claim 16, wherein
the color filter is made of a photosensitive material.

20. The method of claim 16, wherein
the organic light emitting member is aligned to correspond to the color filter.
